(19) United States
(12) Patent Application Publication
(10) Pub. No.: US 2026/0371727 A1
(43) Pub. Date: Nov. 19, 2026

(54) DISPLAY DEVICE AND MANUFACTURING METHOD OF ACTIVE DEVICE SUBSTRATE

(71) Applicant: AUO Corporation, Hsinchu City (TW)

(72) Inventors: Ya-Qin Huang, Hsinchu City (TW); Jia-Hao Du, Hsinchu City (TW); Yi-Da He, Hsinchu City (TW); Kuo-Kuang Chen, Hsinchu City (TW); Chih-Hung Tsai, Hsinchu City (TW)

(73) Assignee: AUO Corporation, Hsinchu City (TW)

(21) Appl. No.: 19/387,542

(22) Filed: Nov. 12, 2025

(30) Foreign Application Priority Data
Mar. 21, 2025 (TW) 114110676

(51) Int. Cl. H10D 86/40; H10D 86/01; H10D 86/60

(52) U.S. Cl. CPC H10D 86/421; H10D 86/0231; H10D 86/451; H10D 86/60

(57) ABSTRACT

A display device includes a substrate, a light shielding layer, a buffer layer, a semiconductor layer, an insulating layer, a first conductive layer, a second conductive layer, a first source, and a first drain. The substrate has a display area and a peripheral area. The display area has a first active device area, and the peripheral area has a calibration mark area. The semiconductor layer is disposed on the buffer layer and is located in the first active device area. The insulating layer is disposed on the semiconductor layer and covers the first active device area and the calibration mark area. The first conductive layer is disposed on the insulating layer and has a first alignment component located on the calibration mark area. The second conductive layer is disposed on the insulating layer, and has a second alignment component located around the first alignment component on the calibration mark area.

### CROSS-REFERENCE TO RELATED APPLICATION

This application claims the priority benefit of Taiwan application serial no. 114110676, filed on Mar. 21, 2025. The entirety of the above-mentioned patent application is hereby incorporated by reference herein and made a part of this specification.

### BACKGROUND

### Technical Field

The disclosure relates to a display device and a manufacturing method of an active device substrate.

### Related Art

In many display devices, thin film transistors are used to perform signal processing, and these thin film transistors may be disposed in driving circuits or in pixel structures. Generally, electrode material layers and semiconductor material layers are deposited by thin film deposition techniques, and patterning processes are performed on these electrode material layers and semiconductor material layers to obtain electrodes and semiconductor layers in the thin film transistor. Generally, photoresist patterns are used as masks to perform the patterning processes. However, during the process of forming photoresist patterns, the formed photoresist patterns may deviate from expected positions as a result of alignment, leading to increased variation in channel length of the thin film transistor and thus affecting the yield of the thin film transistor.

### SUMMARY

At least one embodiment of the disclosure provides a manufacturing method of an active device substrate, including steps below. A substrate is provided, the substrate has a display area and a peripheral area located outside the display area, the display area has at least one sub-pixel area, the sub-pixel area has a first active device area, and the peripheral area has at least one calibration mark area. A light shielding layer is formed on the substrate, and the light shielding layer has a first light shielding part located in the first active device area. A buffer layer is formed on the substrate and covers the first light shielding part. A semiconductor layer is formed on the buffer layer of the substrate, and the semiconductor layer has a first semiconductor part located in the first active device area. An insulating layer is formed on the buffer layer and the semiconductor layer and covers the first active device area and the at least one calibration mark area. A first conductive layer is formed on the insulating layer and covers the first active device area and the at least one calibration mark area. A first photoresist pattern is formed on the first conductive layer, and the first photoresist pattern has a first sub-photoresist part and a second sub-photoresist part respectively located on the first active device area and the at least one calibration mark area. The first conductive layer is etched using the first photoresist pattern as an etching mask to respectively form a first alignment component on the at least one calibration mark area and a first gate part on the first active device area. Using the first gate part and the first sub-photoresist part located in the first active device area as a doping mask, an ion implantation process is performed on the semiconductor layer outside the doping mask to form a first doped area and a first undoped area in the first semiconductor part of the first active device area, and the first photoresist pattern is removed. A second conductive layer is formed on the insulating layer and on the first alignment component and the first gate part and covers the first active device area and the at least one calibration mark area. A second photoresist pattern is formed on the second conductive layer, the second photoresist pattern has a third sub-photoresist part and a fourth sub-photoresist part respectively located on the first active device area and the at least one calibration mark area, the third sub-photoresist part covers a portion of the second conductive layer on the first active device area and an overlapping portion of the second conductive layer overlapped with a portion of the first gate part, and the fourth sub-photoresist part has an opening to expose a portion of the second conductive layer in the at least one calibration mark area. The second conductive layer is etched using the second photoresist pattern as an etching mask to respectively form a second alignment component on the at least one calibration mark area and a second gate part on the first active device area and expose a portion of the first undoped area and a portion of the first doped area, the second alignment component is located around the first alignment component, and portions of the second gate part overlap with the first gate part and the first doped area. Using the second gate part and the third sub-photoresist part located in the first active device area as a heavy doping mask, a heavy doping process is performed on the semiconductor layer outside the heavy doping mask to respectively form two first heavily doped areas in a portion of the first doped area and a portion of the first undoped area of the first active device area, and the first heavily doped areas are separated from each other. An etch-back process is performed on the second gate part and the first gate part to reduce widths of the second gate part and the first gate part and expose a portion of the first doped area and a portion of the first undoped area located in the first active device area, and the second photoresist pattern is removed. Using the second gate part located in the first active device area as a light doping mask, a light doping process is performed on the semiconductor layer outside the light doping mask to form a first lightly doped area in a portion of the first undoped area of the first active device area. A first source and a first drain are formed on the insulating layer to be respectively electrically connected to the first heavily doped areas of the first active device area.

At least one embodiment of the disclosure provides a display device including a substrate, a light shielding layer, a buffer layer, a semiconductor layer, an insulating layer, a first conductive layer, a second conductive layer, a first source, and a first drain. The substrate has a display area and a peripheral area located outside the display area, the display area has at least one sub-pixel area, the sub-pixel area has a first active device area, and the peripheral area has at least one calibration mark area. The light shielding layer is disposed on the substrate and has a first light shielding part located in the first active device area. The buffer layer is disposed on the substrate and covers the first light shielding part. The semiconductor layer is disposed on the buffer layer of the substrate and has a first semiconductor part located in the first active device area, the first semiconductor part has a first doped area, a first undoped area, a first lightly doped area, and two first heavily doped areas, the first doped area, the first undoped area, and the first lightly doped area are located between the first heavily doped areas, the first doped area is located between the first undoped area and one of the first heavily doped areas, and the first lightly doped area is located between the first undoped area and the other of the first heavily doped areas. The insulating layer is disposed on the buffer layer and the semiconductor layer and covers the first active device area and the at least one calibration mark area. The first conductive layer is disposed on the insulating layer and has a first alignment component located on the at least one calibration mark area and a first gate part located on the first active device area, and the first gate part overlaps with the first undoped area. The second conductive layer is disposed on the insulating layer and has a second alignment component located on the at least one calibration mark area and a second gate part located on the first active device area, the second alignment component is located around the first alignment component, portions of the second gate part overlap with the first gate part and the first doped area, and the first gate part and the second gate part constitute a first gate. The first source and the first drain are disposed on the insulating layer and respectively electrically connected to the first heavily doped areas of the first active device area.

### BRIEF DESCRIPTION OF THE DRAWINGS

FIG. 1 is a schematic top view of a display device according to an embodiment of the disclosure.

FIG. 2 is a schematic cross-sectional view of a display device according to an embodiment of the disclosure.

FIG. 3A to FIG. 3O are schematic cross-sectional views of various stages of manufacturing the display device of FIG. 2.

FIG. 4A is a top view of a calibration mark area according to an embodiment of the disclosure.

FIG. 4B is a top view of a calibration mark area according to another embodiment of the disclosure.

FIG. 5A is a cross-sectional view of the calibration mark area of FIG. 4A.

FIG. 5B is a cross-sectional view of the calibration mark area of FIG. 4B.

FIG. 6 shows an overlay distribution of a first gate part and a second gate part after disposing a first alignment component.

FIG. 7 shows an I-V curve at different voltages of a thin film transistor manufactured according to an embodiment of the disclosure.

### DESCRIPTION OF THE EMBODIMENTS

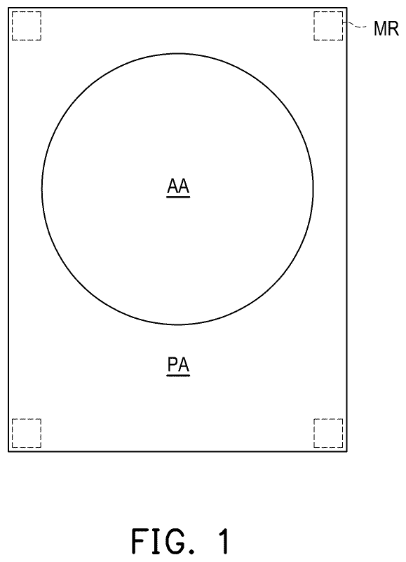

FIG. 1 is a schematic top view of a display device according to an embodiment of the disclosure. Referring to FIG. 1, a substrate 100 of the display device has a display area AA and a peripheral area PA surrounding the display area AA. The shape of the display area AA may be adjusted according to requirements and may be, for example, rectangular, circular, elliptical, or other suitable shapes.

An array of pixel structures is disposed on the display area AA, and each pixel structure includes active devices (e.g., thin film transistors), passive devices (e.g., capacitors), and other suitable devices. In some embodiments, the pixel structure further includes display units such as micro light emitting diodes, organic light emitting diodes, liquid crystal media, electrophoretic media, or other suitable components.

Various circuit structures are disposed on the peripheral area PA, and these circuit structures are configured to, for example, provide signals to the pixel structures on the display area AA. In this embodiment, the peripheral area PA includes a calibration mark area MR. A mark used for detecting/calibrating an exposure process during the manufacturing of the display device is disposed on the calibration mark area MR. The calibration mark area MR may be located at any position in the peripheral area PA. In this embodiment, the calibration mark area MR is located at four corners of the peripheral area PA, but the disclosure is not limited thereto. In other embodiments, the calibration mark area MR may also be provided at other positions.

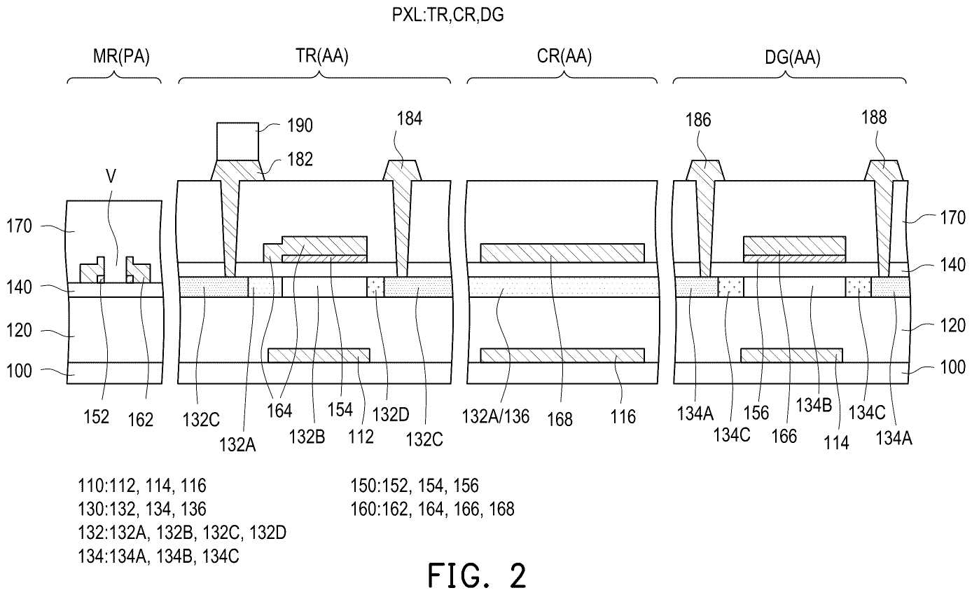

FIG. 2 is a schematic cross-sectional view of a display device according to an embodiment of the disclosure. FIG. 2 partially shows the display area AA and the peripheral area PA of FIG. 1. Referring to FIG. 2, the display device 10 includes a substrate 100, a light shielding layer 110, a buffer layer 120, a semiconductor layer 130, an insulating layer 140, a first conductive layer 150, a second conductive layer 160, an interlayer dielectric layer 170, a first source 182, a first drain 184, a second source 186, a second drain 188, and a display unit 190.

The substrate 100 has a display area AA and a peripheral area PA located outside the display area AA. The display area AA has at least one sub-pixel area PXL. The sub-pixel area PXL has a first active device area TR, a second active device area DG, and a capacitor area CR. The peripheral area PA has at least one calibration mark area MR.

The first active device area TR includes a thin film transistor, particularly, a protrusion gate channel bridge thin film transistor (PGCB TFT). The thin film transistor includes a first light shielding part 112, a first semiconductor part 132, a first gate part 154, a second gate part 164, a first source 182, and a first drain 184.

The second active device area DG includes a double gate transistor structure. The double gate transistor structure includes a second light shielding part 114, a second semiconductor part 134, a third gate part 156, a fourth gate part 166, a second source 186, and a second drain 188.

The capacitor area CR includes a capacitor. The capacitor includes a third light shielding part 116, a third semiconductor part 136, and an electrode 168.

The calibration mark area MR includes a first alignment component 152 and a second alignment component 162.

In some embodiments, the structure of the sub-pixel area PXL may be represented by nTmC, where T is the number of transistors in the sub-pixel area PXL, C is the number of capacitors in the sub-pixel area PXL, n and m are positive integers, and n>m. Thus, there may be various combinations of the number of transistors and the number of capacitors in the sub-pixel area PXL, such as 2T1C/3T1C/4T1C/5T1C/6T1C/4T2C/5T2C/6T2C/7T2C/7T1C, etc., and the disclosure is not limited thereto. In this embodiment, the sub-pixel area PXL has a 2T1C configuration. 2T means that the sub-pixel area PXL has two transistors, or two active devices, which are respectively the thin film transistor in the first active device area TR serving as a driving device or an emitting controller, and the double gate transistor in the second active device area DG serving as a switch. 1C means that the sub-pixel area PXL has one capacitor, namely the capacitor in the capacitor area CR.

Referring to FIG. 2, as shown in FIG. 2, the light shielding layer 110 is disposed on the substrate 100, and has a first light shielding part 112 located in the first active device area TR, a second light shielding part 114 located in the second active device area DG, and a third light shielding part 116 located in the capacitor area CR. In this embodiment, the first light shielding part 112, the second light shielding part 114, and the third light shielding part 116 are separated from each other, but the disclosure is not limited thereto. In other embodiments, any two or more of the first light shielding part 112, the second light shielding part 114, and the third light shielding part 116 are connected to each other.

The buffer layer 120 is disposed on the substrate 100, and extends from the first active device area TR to the capacitor area CR and the second active device area DG, and extends to the calibration mark area MR. The buffer layer 120 covers the first light shielding part 112, the second light shielding part 114, and the third light shielding part 116. Specifically, in this embodiment, the buffer layer 120 covers the top surface of the first light shielding part 112, the top surface of the second light shielding part 114, and the top surface of the third light shielding part 116. In other words, the first light shielding part 112, the second light shielding part 114, and the third light shielding part 116 are located between the buffer layer 120 and the substrate 100.

The semiconductor layer 130 is disposed on the buffer layer 120 of the substrate 100, and has a first semiconductor part 132 located in the first active device area TR, a second semiconductor part 134 located in the second active device area DG, and a third semiconductor part 136 located in the capacitor area CR.

In the first active device area TR, the first semiconductor part 132 has a first doped area 132A, a first undoped area 132B, a first lightly doped area 132D, and two first heavily doped areas 132C. The first doped area 132A, the first undoped area 132B, and the first lightly doped area 132D are located between the first heavily doped areas 132C. The first doped area 132A is located between the first undoped area 132B and one of the first heavily doped areas 132C, and the first lightly doped area 132D is located between the first undoped area 132B and the other of the first heavily doped areas 132C. The first undoped area 132B is also referred to as a channel area, has a lower doping concentration (or is undoped), and has the highest resistivity. The first heavily doped areas 132C have a higher doping concentration and have the lowest resistivity. The doping concentration of the first lightly doped area 132D is lower than the doping concentration of the first heavily doped areas 132C, and the resistivity of the first lightly doped area 132D is higher than the resistivity of the first heavily doped areas 132C. In addition, in some embodiments, the doping concentrations of the two first heavily doped areas 132C may be the same as or different from each other.

In the second active device area DG, the second semiconductor part 134 has a second undoped area 134B, two second lightly doped areas 134C, and two second heavily doped areas 134A. The second undoped area 134B and the second lightly doped areas 134C are located between the second heavily doped areas 134A. One of the second lightly doped areas 134C is located between the second undoped area 134B and one of the second heavily doped areas 134A. The other of the second lightly doped areas 134C is located between the second undoped area 134B and the other of the second heavily doped areas 134A. The second undoped area 134B has a lower doping concentration (or is undoped) and has the highest resistivity. The second heavily doped areas 134A have a higher doping concentration and have the lowest resistivity. The doping concentration of the second lightly doped areas 134C is lower than the doping concentration of the second heavily doped areas 134A, and the resistivity of the second lightly doped areas 134C is higher than the resistivity of the second heavily doped areas 134A. In addition, in some embodiments, the doping concentrations of the two second heavily doped areas 134A may be the same as or different from each other. In some embodiments, the doping concentrations of the two second lightly doped areas 134C may be the same as or different from each other. Furthermore, the doping concentration of the first heavily doped areas 132C is substantially the same as the doping concentration of the second heavily doped areas 134A, and the first heavily doped areas 132C and the second heavily doped areas 134A have similar resistivity.

In the capacitor area CR, the third semiconductor part 136 has a first doped area 132A. In some embodiments, the first doped area extends from the first semiconductor part 132 to the third semiconductor part. In other embodiments, the first doped area 132A of the first semiconductor part 132 and the first doped area 132A of the third semiconductor part 136 are not connected to each other.

The insulating layer 140 is disposed on the buffer layer 120 and the semiconductor layer 130 and covers the first active device area TR, the second active device area DG, the capacitor area CR, and at least one calibration mark area MR.

The first conductive layer 150 is disposed on the insulating layer 140, and has a first alignment component 152 located on at least one calibration mark area MR, a first gate part 154 located on the first active device area TR, and a third gate part 156 located on the second active device area DG. In the first active device area TR, the first gate part 154 overlaps with the first undoped area 132B. In the second active device area DG, the third gate part 156 overlaps with the second undoped area 134B.

The second conductive layer 160 is disposed on the insulating layer 140, and has a second alignment component 162 located on at least one calibration mark area MR, a second gate part 164 located on the first active device area TR, a fourth gate part 166 located on the second active device area DG, and an electrode 168 located on the capacitor area CR. In the calibration mark area MR, the second alignment component 162 is located around the first alignment component 152.

The second alignment component 162 partially overlaps with the first alignment component 152, and there is a via V at the overlapping portion of the second alignment component 162 and the first alignment component 152. For example, both the first alignment component 152 and the second alignment component 162 have a via V and overlap with each other. In other words, the via wall of the second alignment component 162 overlaps and connects with the via wall of the first alignment component 152. In some embodiments, at least one of the first alignment component 152 and the second alignment component 162 has a via V. In this embodiment, both the first alignment component 152 and the second alignment component 162 have a via V. In other embodiments, only the second alignment component 162 has a via V and the first alignment component 152 does not have a via V, or only the first alignment component 152 has a via V and the second alignment component 162 does not have a via V.

In some embodiments, either one of the first alignment component 152 and the second alignment component 162 may be opened (i.e., the first alignment component 152 and the second alignment component 162 may have gaps or interruptions in a top view) or non-opened (i.e., the first alignment component 152 and the second alignment component 162 are complete without gaps or interruptions in a top view).

In the first active device area TR, the second gate part 164 partially overlaps with the first gate part 154 and the first doped area 132A. The first gate part 154 and the second gate part 164 constitute a first gate.

In the second active device area DG, the fourth gate part 166 and the third gate part 156 overlap with the second undoped area 134B.

In the capacitor area CR, the electrode 168 overlaps with a portion of the first doped area 132A.

The interlayer dielectric layer 170 is located on the second alignment component 162, the second gate part 164, the fourth gate part 166, the electrode 168, and the insulating layer 140, and covers the second alignment component 162, the second gate part 164, the fourth gate part 166, the electrode 168, and the insulating layer 140.

In the first active device area TR, the first source 182 and the first drain 184 are disposed on the interlayer dielectric layer 170 to be electrically connected to the first heavily doped areas 132C of the first active device area TR, respectively. In this embodiment, the first source 182 and the first drain 184 are located on the interlayer dielectric layer 170 and are connected to the first heavily doped areas 132C of the first semiconductor part 132 through via holes in the interlayer dielectric layer 170 and the insulating layer 140.

In the second active device area DG, the second source 186 and the second drain 188 are located on the interlayer dielectric layer 170 to be electrically connected to the second heavily doped areas 134A of the second active device area DG, respectively. In this embodiment, the second source 186 and the second drain 188 are located on the interlayer dielectric layer 170 and are connected to the second heavily doped areas 134A of the second semiconductor part 134 through via holes in the interlayer dielectric layer 170 and the insulating layer 140.

A self-luminous component 190 is disposed on the substrate 100 and is electrically connected to the first drain 184 or the first source 182 on the first active device area TR. In some embodiments, the self-luminous component 190 is, for example, a micro light emitting diode, an organic light emitting diode, a liquid crystal medium, an electrophoretic display medium, or other suitable components.

As shown in FIG. 2, the first light shielding part 112, the buffer layer 120, the first semiconductor part 132, the insulating layer 140, the first gate part 154, the second gate part 164, the first source 182, and the first drain 184 on the first active device area TR constitute a first active device, and the first gate part 154 and the second gate part 164 constitute a first gate. In this embodiment, the first gate has two heights, which are respectively the height of the second gate part 164, i.e., the height of the second conductive layer 160, and the sum of the height of the first gate part 154 and the height of the second gate part 164, i.e., the sum of the height of the first conductive layer 150 and the height of the second conductive layer 160.

As shown in FIG. 2, the second light shielding part 114, the buffer layer 120, the second semiconductor part 134, the insulating layer 140, the third gate part 156, the fourth gate part 166, the second source 186, and the second drain 188 on the second active device area DG constitute a second active device, and the third gate part 156 and the fourth gate part 166 constitute a second gate. In this embodiment, the height of the second gate is the sum of the height of the third gate part 156 and the height of the fourth gate part 166, i.e., the sum of the height of the first conductive layer 150 and the height of the second conductive layer 160.

As shown in FIG. 2, the third light shielding part 116, the buffer layer 120, the third semiconductor part 136, the insulating layer 140, and the electrode 168 on the capacitor area CR constitute a capacitor. In this embodiment, the height of the electrode 168 is the height of the second conductive layer 160.

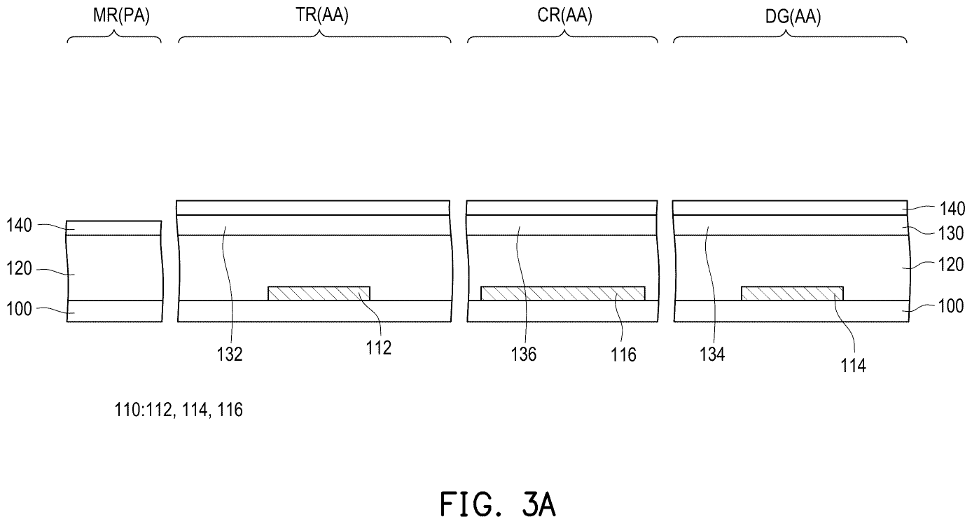

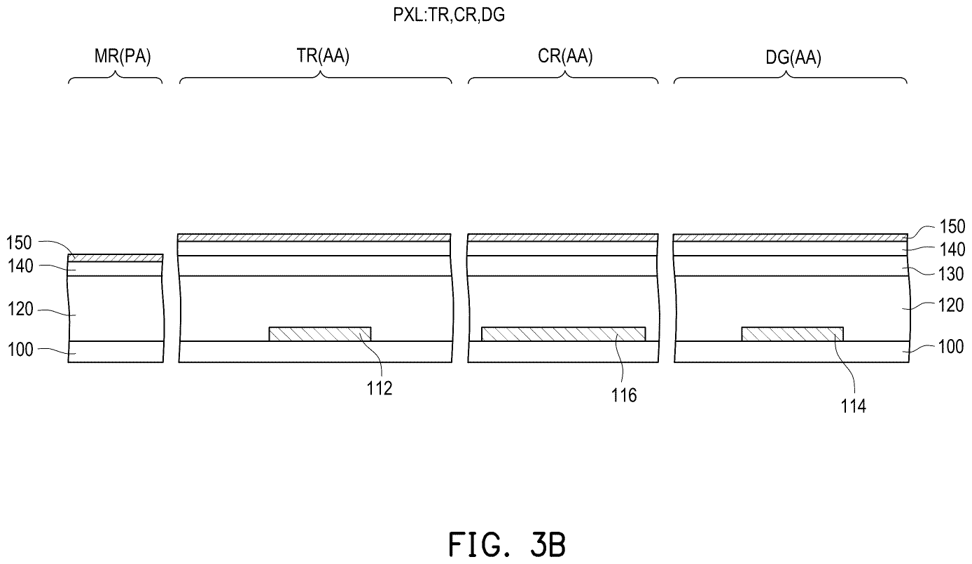

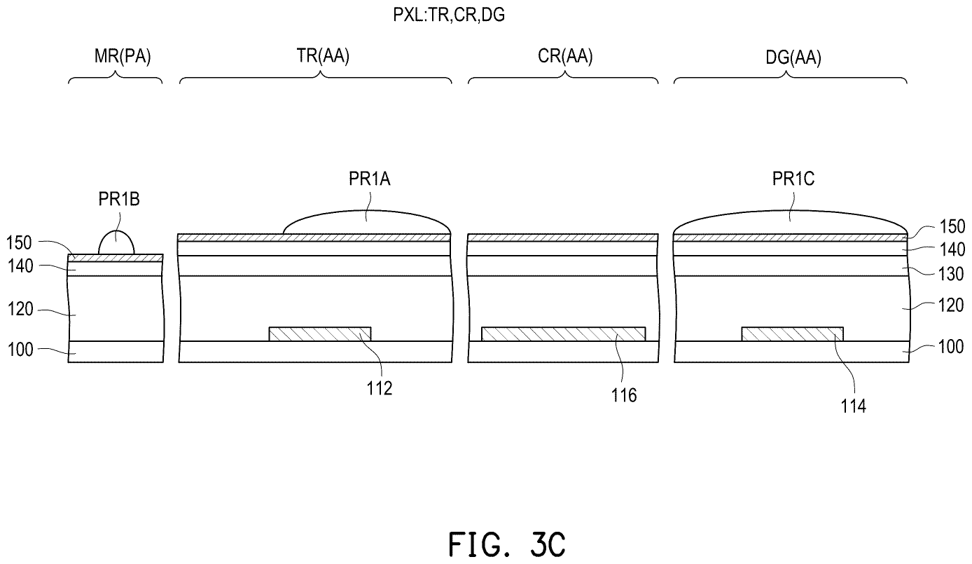

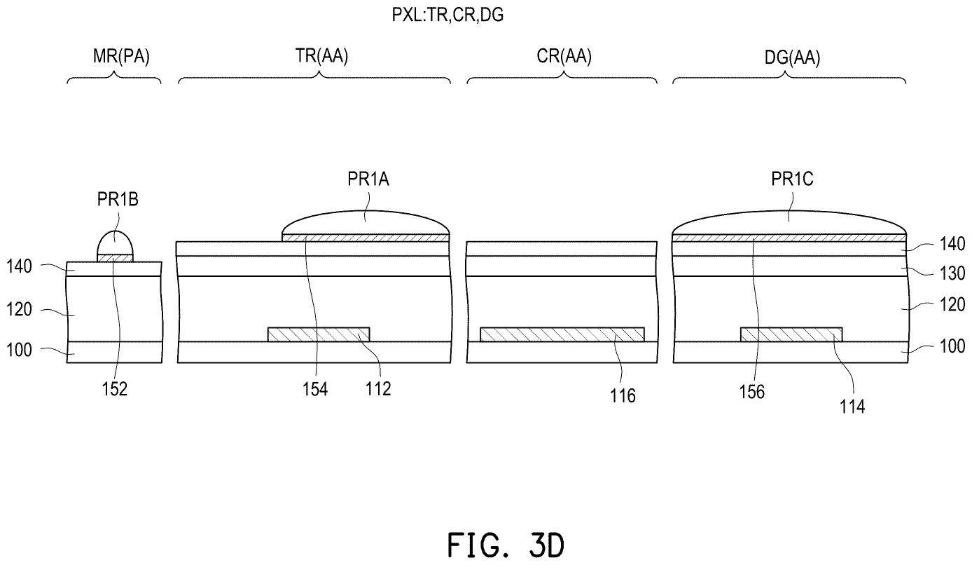

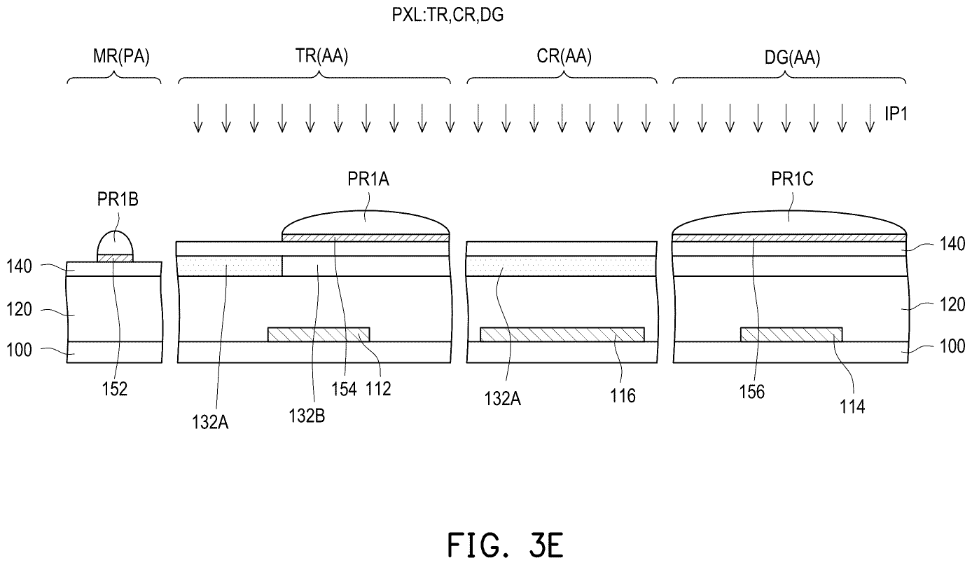

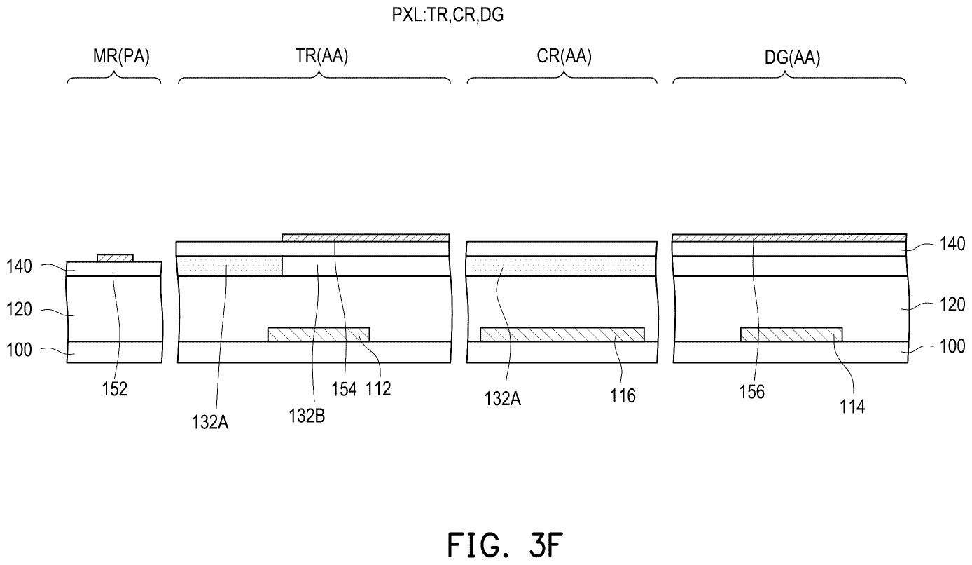

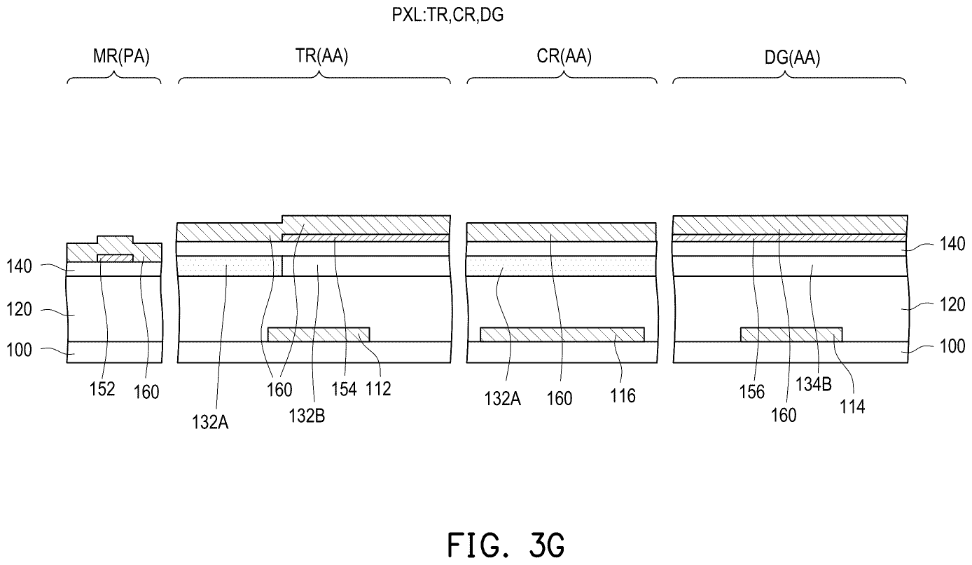

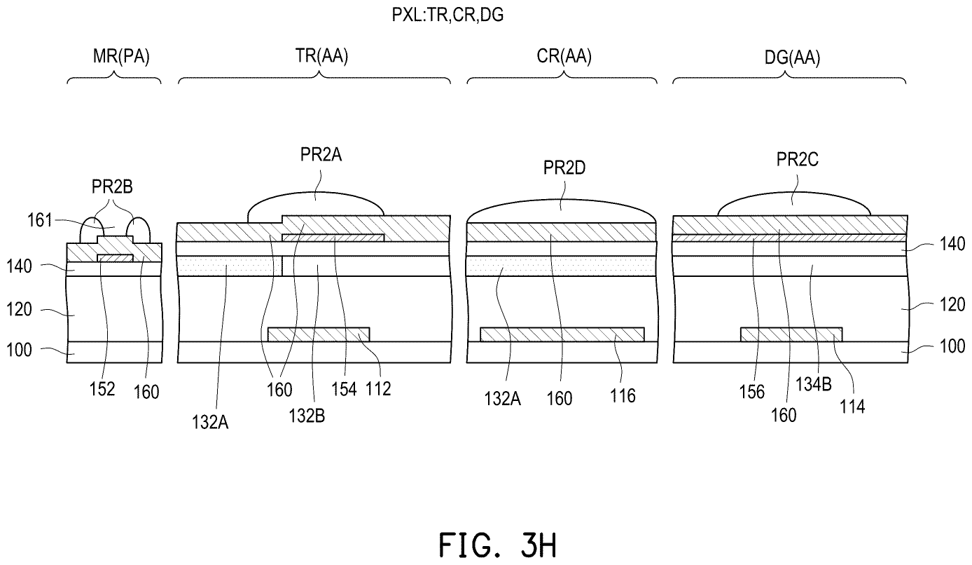

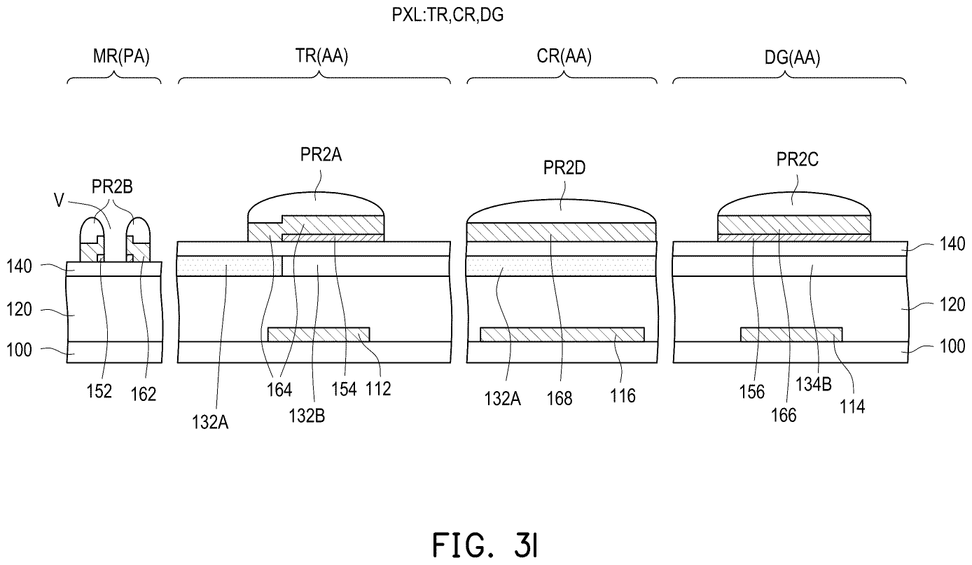

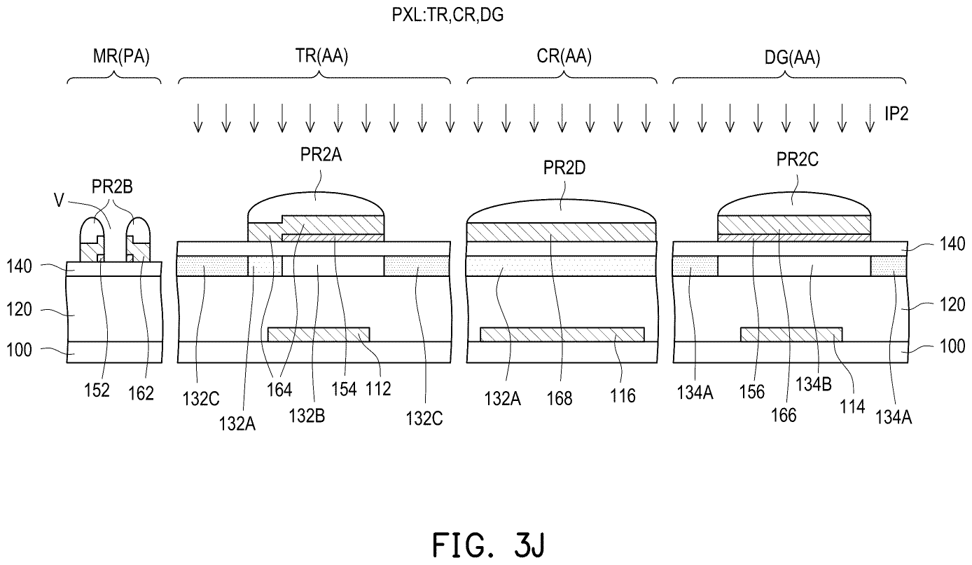

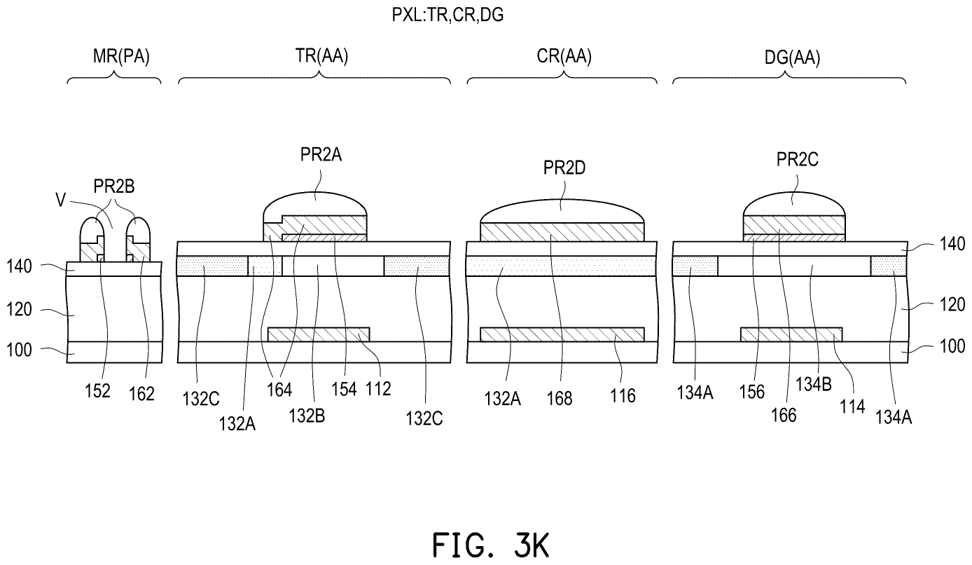

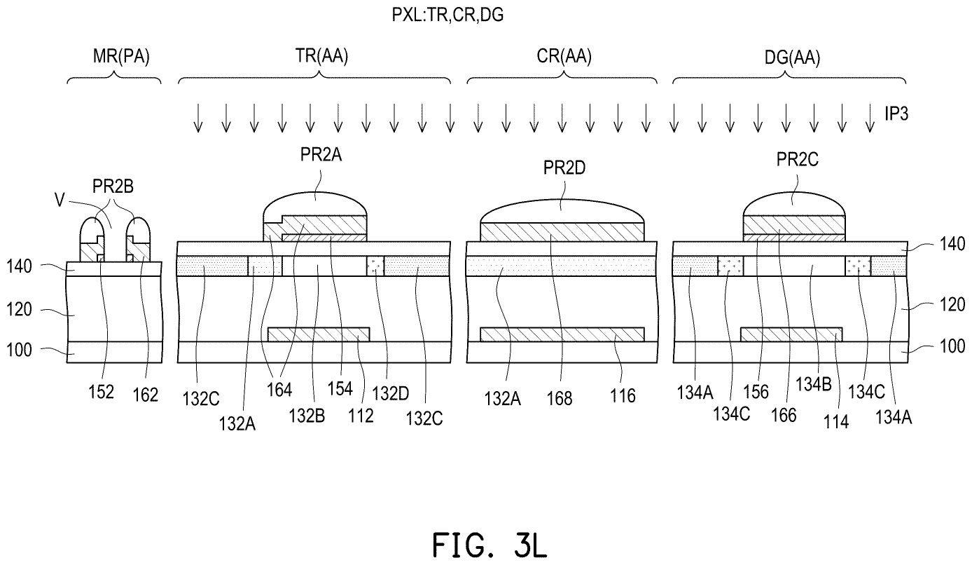

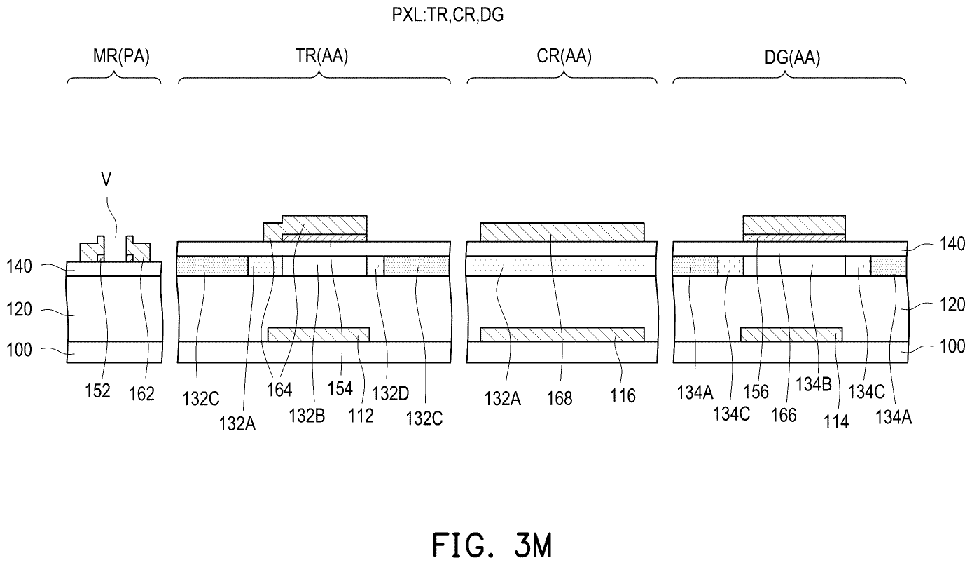

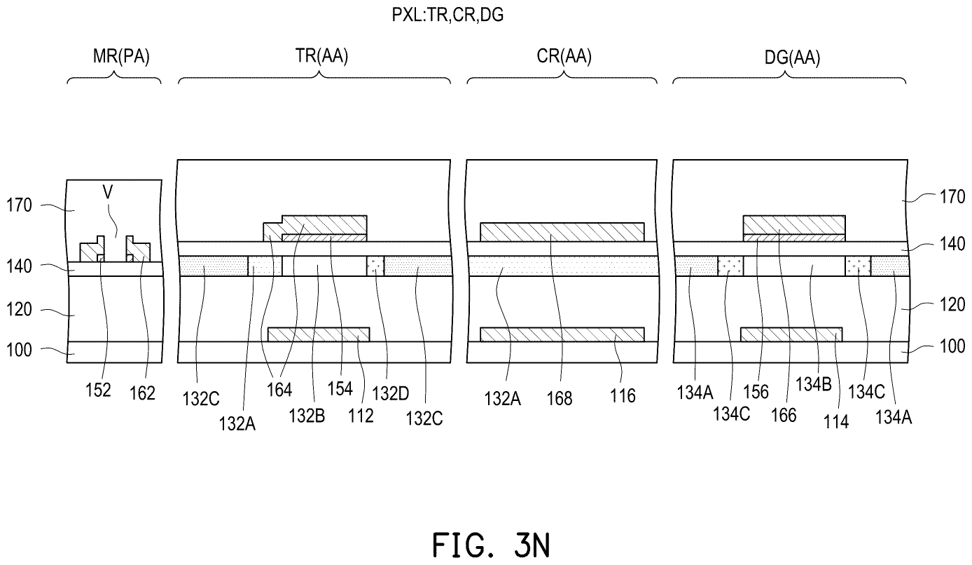

FIG. 3A to FIG. 3O are schematic cross-sectional views of various stages of manufacturing the display device of FIG. 2.

Referring to FIG. 3A, a substrate 100 is provided. The substrate 100 has a display area AA and a peripheral area PA located outside the display area AA. The display area AA has at least one sub-pixel area PXL. The sub-pixel area PXL has a first active device area TR, and the peripheral area PA has at least one calibration mark area MR.

In some embodiments, the substrate 100 is, for example, a rigid substrate, and its material may be glass, quartz, organic polymer, opaque/reflective material (e.g., conductive material, metal, wafer, ceramic, or other applicable materials), or other applicable materials. However, the disclosure is not limited thereto. In other embodiments, the substrate 100 may also be a flexible substrate or a stretchable substrate. For example, materials of the flexible substrate and the stretchable substrate include polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (PU), or other suitable materials.

In the embodiment of FIG. 3A, a buffer layer 120 is formed on the substrate 100 and covers the first light shielding part 112 located in the first active device area TR, the second light shielding part 114 located in the second active device area DG, the third light shielding part 116 located in the capacitor area CR, and at least one calibration mark area MR.

In some embodiments, at least one of the first light shielding part 112, the second light shielding part 114, and the third light shielding part 116 may have a single-layer or multi-layer structure, and its material includes metals such as chromium, gold, silver, copper, tin, lead, hafnium, tungsten, molybdenum, neodymium, titanium, tantalum, aluminum, zinc, nickel, etc., alloys thereof, metal oxides thereof, metal nitrides thereof, combinations thereof, or other conductive materials. In some embodiments, the first light shielding part 112, the second light shielding part 114, and the third light shielding part 116 may have transparent materials, reflective materials, light-absorbing (blackening) materials, or other suitable materials. In some embodiments, if the first light shielding part 112, the second light shielding part 114, and the third light shielding part 116 have multi-layer structures, their materials may be the same material or different materials. In some embodiments, when the first light shielding part 112, the second light shielding part 114, and the third light shielding part 116 have reflective materials or stacks of reflective materials and transparent materials, in addition to serving to shield and prevent light from the outer surface of the substrate 100 from entering the semiconductor layer 130, the first light shielding part 112, the second light shielding part 114, and the third light shielding part 116 may also serve as bottom gates of the first active device area TR and/or the second active device area DG and electrode of the capacitor area CR. In some embodiments, the method of forming the first light shielding part 112, the second light shielding part 114, and the third light shielding part 116 includes the following. First, a conductive material layer is formed on the substrate 100. Next, the conductive material layer is patterned to form the first light shielding part 112, the second light shielding part 114, and the third light shielding part 116. In some embodiments, the method of forming the conductive material layer includes sputtering, electroplating, electroless plating, physical vapor deposition, chemical vapor deposition, or other suitable processes.

In the embodiment of FIG. 3A, the first light shielding part 112, the second light shielding part 114, and the third light shielding part 116 are in direct contact with the substrate 100, but the disclosure is not limited thereto. In other embodiments, a buffer layer is first formed on the substrate 100, and then the first light shielding part 112, the second light shielding part 114, and the third light shielding part 116 are formed on the buffer layer.

In some embodiments, the buffer layer 120 has a single-layer or multi-layer structure, and its material includes silicon oxide, silicon nitride, silicon oxynitride, zirconium oxide, hafnium oxide, aluminum oxide, organic insulating materials, other suitable materials, or combinations thereof. In some embodiments, multiple layers in the multi-layer structure of the buffer layer 120 may have the same material or different materials. In some embodiments, the method of forming the buffer layer 120 includes physical vapor deposition, chemical vapor deposition, atomic layer deposition, coating, or other suitable processes. In some embodiments, the thickness of the buffer layer 120 is 500 angstroms to 10000 angstroms.

In the embodiment of FIG. 3A, a semiconductor layer 130 is formed on the buffer layer 120 of the substrate 100, and the semiconductor layer 130 has a first semiconductor part 132 located in the first active device area TR, a second semiconductor part 134 located in the second active device area DG, and a third semiconductor part 136 located in the capacitor area CR. The semiconductor layer 130 does not extend to the calibration mark area MR.

The first semiconductor part 132, the second semiconductor part 134, and the third semiconductor part 136 of the semiconductor layer 130 have the same material. In some embodiments, the first semiconductor part 132, the second semiconductor part 134, and the third semiconductor part 136 each have a single-layer or multi-layer structure, and include silicon-containing semiconductor materials, such as amorphous silicon, polycrystalline silicon, microcrystalline silicon, monocrystalline silicon, oxide semiconductor materials (e.g., indium zinc oxide, indium gallium zinc oxide, other suitable materials, or combinations thereof), other suitable materials, or combinations thereof. In some embodiments, polycrystalline silicon is adopted. In some embodiments, the method of forming the first semiconductor part 132, the second semiconductor part 134, and the third semiconductor part 136 of the semiconductor layer 130 includes the following. First, a semiconductor layer 130 is formed on the buffer layer 120. Next, the semiconductor layer 130 is patterned to form the first semiconductor part 132, the second semiconductor part 134, and the third semiconductor part 136.

In the embodiment of FIG. 3A, an insulating layer 140 is formed on the buffer layer 120 and the semiconductor layer 130 and covers the first active device area TR, the second active device area DG, the capacitor area CR, and at least one calibration mark area MR.

In some embodiments, the insulating layer 140 has a single-layer or multi-layer structure, and its material includes silicon oxide, silicon nitride, silicon oxynitride, zirconium oxide, hafnium oxide, aluminum oxide, organic insulating materials, other suitable materials, or combinations thereof. In some embodiments, multiple layers in the multi-layer structure of the insulating layer 140 may have the same material or different materials. In some embodiments, the method of forming the insulating layer 140 includes physical vapor deposition, chemical vapor deposition, atomic layer deposition, coating, or other suitable processes. In some embodiments, the thickness of the insulating layer 140 is 200 angstroms to 2000 angstroms.

Referring to FIG. 3B, a first conductive layer 150 is formed on the insulating layer 140 and covers the first active device area TR, the second active device area DG, the capacitor area CR, and at least one calibration mark area MR. In some embodiments, the first conductive layer 150 has a single-layer or multi-layer structure, and its material includes metals such as chromium, gold, silver, copper, tin, lead, hafnium, tungsten, molybdenum, neodymium, titanium, tantalum, aluminum, zinc, nickel, etc., alloys thereof, metal oxides thereof, metal nitrides thereof, combinations thereof, or other conductive materials. In some embodiments, multiple layers in the multi-layer structure of the first conductive layer 150 may have the same material or different materials. In some embodiments, the method of forming the first conductive layer 150 includes sputtering, electroplating, electroless plating, physical vapor deposition, chemical vapor deposition, or other suitable processes. In some embodiments, the thickness of the first conductive layer 150 is greater than 500 A, but the disclosure is not limited thereto.

Referring to FIG. 3C, a first photoresist pattern PR1 is formed on the first conductive layer 150. The first photoresist pattern PR1 has a first sub-photoresist part PR1A located in the first active device area TR, a fifth photoresist part PR1C located on the second active device area DG, and a second sub-photoresist part PR1B located on at least one calibration mark area MR. Specifically, an entire photoresist material layer is first formed on the first conductive layer 150. Then, an exposure process is performed on the photoresist material layer using a photomask to form the first sub-photoresist part PR1A, the fifth photoresist part PR1C, and the second sub-photoresist part PR1B.

Referring to FIG. 3D, the first conductive layer 150 is etched using the first photoresist pattern PR1 as an etching mask. Specifically, a first alignment component 152 is formed in at least one calibration mark area MR using the second sub-photoresist part PR1B as an etching mask, and a first gate part 154 is formed on the first active device area TR using the first sub-photoresist part PR1A as an etching mask. The first conductive layer 150 is etched using the fifth photoresist part PR1C as an etching mask to form a third gate part 156 on the second active device area DG. On the other hand, the first conductive layer 150 is etched to expose the insulating layer 140 on the capacitor area CR. In some embodiments, the etching process includes a dry etching process, a wet etching process, or other suitable processes.

Referring to FIG. 3E, using the first gate part 154 and the first sub-photoresist part PR1A located in the first active device area TR, and the third gate part 156 and the fifth photoresist part PR1C located in the second active device area DG as a doping mask, an ion implantation process IP1 is performed on the semiconductor layer 130 outside the doping mask to form a first doped area 132A and a first undoped area 132B in the first semiconductor part 132 of the first active device area TR, and form a first doped area 132A in the third semiconductor part 136 of the capacitor area CR.

In some embodiments, the first doped area 132A of the first semiconductor part 132 and the first doped area 132A of the third semiconductor part 136 include P-type silicon semiconductor, and the dopant selected for the ion implantation process IP1 is aluminum (Al), boron (B), gallium (Ga), or other suitable materials. In some embodiments, the first doped area 132A of the first semiconductor part 132 and the first doped area 132A of the third semiconductor part 136 include N-type silicon semiconductor, and the dopant selected for the ion implantation process IP1 is antimony (Sb), arsenic (As), phosphorus (P), or other suitable materials. In some embodiments, the ion implantation process IP1 may be referred to as a heavy doping process, and the first doped area 132A of the first semiconductor part 132 and the first doped area 132A of the third semiconductor part 136 may be referred to as P+ areas or N+ areas.

Referring to FIG. 3F, the first photoresist pattern PR1 is removed, including the first sub-photoresist part PR1A located in the first active device area TR, the fifth photoresist part PR1C located in the second active device area DG, and the second sub-photoresist part PR1B located in the calibration mark area MR. In some embodiments, the first photoresist pattern PR1 is removed by an ashing process, a stripping process, or other suitable processes.

Since the first conductive layer 150 is used as the doping mask for the ion implantation process IP1, after the ion implantation process IP1 is ended and the first photoresist pattern PR1 is removed, the first alignment component 152 in the calibration mark area MR may be used to mark the positions of the first doped area 132A, the first undoped area 132B, and the first gate part 154.

Referring to FIG. 3G, a second conductive layer 160 is formed on the insulating layer 140, the first gate part 154, the third gate part 156, and the first alignment component 152, and covers the first active device area TR, the second active device area DG, and at least one calibration mark area MR. The second conductive layer 160 also covers the capacitor area CR. In some embodiments, the second conductive layer 160 has a single-layer or multi-layer structure, and its material includes metals such as chromium, gold, silver, copper, tin, lead, hafnium, tungsten, molybdenum, neodymium, titanium, tantalum, aluminum, zinc, nickel, etc., alloys thereof, metal oxides thereof, metal nitrides thereof, combinations thereof, or other conductive materials. In some embodiments, multiple layers in the multi-layer structure of the second conductive layer 160 may have the same material or different materials. In some embodiments, the method of forming the second conductive layer 160 includes sputtering, electroplating, electroless plating, physical vapor deposition, chemical vapor deposition, or other suitable processes. In some embodiments, the first conductive layer 150 and the second conductive layer 160 have the same material as each other.

Referring to FIG. 3H, a second photoresist pattern PR2 is formed on the second conductive layer 160. The second photoresist pattern PR2 has a third sub-photoresist part PR2A located in the first active device area TR, a sixth photoresist part PR2C located in the second active device area DG, a seventh photoresist part PR2D located in the capacitor area CR, and a fourth sub-photoresist part PR2B located in at least one calibration mark area MR. Specifically, an entire photoresist material layer is first formed on the second conductive layer 160. Then, an exposure process is performed on the photoresist material layer using a photomask to form the third sub-photoresist part PR2A, the sixth photoresist part PR2C, the seventh photoresist part PR2D, and the fourth sub-photoresist part PR2B.

In the first active device area TR, the third sub-photoresist part PR2A covers a portion of the second conductive layer 160 on the first active device area TR, and an overlapping portion of the second conductive layer 160 overlapped with a portion of the first gate part 154.

In the second active device area DG, the sixth photoresist part PR2C covers a portion of the second conductive layer 160 on the second active device area DG, and an overlapping portion of the second conductive layer 160 overlapped with a portion of the third gate part 156.

In at least one calibration mark area MR, the fourth sub-photoresist part PR2B has an opening 161 to expose a portion of the second conductive layer 160 in the at least one calibration mark area MR.

In the exposure process, the equipment and/or photomask used for the exposure process is aligned according to the first alignment component 152. For example, the first alignment component 152 is irradiated with light, and the position of the first alignment component 152 is confirmed according to the transmission and/or reflection of the light, to thus determine the exposure position of the photoresist material layer. After performing the exposure process, a development process is performed to remove unwanted portions of the photoresist material layer, leaving the third sub-photoresist part PR2A located in the first active device area TR, the sixth photoresist part PR2C located in the second active device area DG, the seventh photoresist part PR2D located in the capacitor area CR, and the fourth sub-photoresist part PR2B located in at least one calibration mark area MR, which together form the second photoresist pattern PR2.

In this embodiment, the fourth sub-photoresist part PR2B overlaps with the first alignment component 152, and the positions of the fourth sub-photoresist part PR2B and the first alignment component 152 are measured to confirm whether the exposure process has been precisely performed. For example, with the fourth sub-photoresist part PR2B and the first alignment component 152, the relative positions of the fourth sub-photoresist part PR2B and the first alignment component 152 are confirmed according to the transmission and/or reflection of light, to thus obtain process shift parameters of the exposure process for the third sub-photoresist part PR2A, the sixth photoresist part PR2C, the seventh photoresist part PR2D, and the fourth sub-photoresist part PR2B of the second photoresist pattern PR2. If an excessive shift occurs in the exposure process of the second photoresist pattern PR2, the second photoresist pattern PR2 may be removed, and the exposure process may be corrected using the obtained process shift parameters. A photoresist material layer is formed again on the second conductive layer 160, and the photoresist material layer is exposed with the corrected exposure process. According to this method, process yield can be improved.

Referring to FIG. 3I, the second conductive layer 160 is etched using the second photoresist pattern PR2 as an etching mask. Specifically, using the third sub-photoresist part PR2A as an etching mask, a second gate part 164 is formed on the first active device area TR, and a portion of the first undoped area 132B and a portion of the first doped area 132A are exposed. A portion of the second gate part 164 overlaps with the first gate part 154 and the first doped area 132A. Using the sixth photoresist part PR2C as an etching mask, the second conductive layer 160 is etched to form a fourth gate part 166 on the second active device area DG and expose a portion of the second semiconductor part 134. The fourth gate part 166 and the third gate part 156 overlap with each other. Using the seventh photoresist part PR2D as an etching mask, the second conductive layer 160 is etched to form an electrode 168 on the capacitor area CR, and the electrode 168 overlaps with a portion of the first doped area 132A. Using the fourth sub-photoresist part PR2B as an etching mask, the second conductive layer 160 is etched to form a second alignment component 162 in at least one calibration mark area MR, and the second alignment component 162 is located around the first alignment component 152. The second alignment component 162 partially overlaps with the first alignment component 152, and there is a via V at the overlapping portion of the second alignment component 162 and the first alignment component 152. In some embodiments, the etching process includes a dry etching process, a wet etching process, or other suitable processes.

Referring to FIG. 3J, using the second gate part 164 and the third sub-photoresist part PR2A located in the first active device area TR, and the fourth gate part 166 and the sixth photoresist part PR2C located in the second active device area DG as a heavy doping mask, a heavy doping process IP2 is performed on the semiconductor layer 130 outside the heavy doping mask to form two first heavily doped areas 132C in a portion of the first doped area 132A and a portion of the first undoped area 132B in the first active device area TR, where the first heavily doped areas 132C are separated from each other, and to form two second heavily doped areas 134A and a second undoped area 134B in portions of the second semiconductor part 134 in the second active device area DG, where the second heavily doped areas 134A are separated from each other.

In some embodiments, the first heavily doped area 132C in the first semiconductor part 132 and the second heavily doped area 134A in the second semiconductor part 134 include P-type silicon semiconductor, and the dopant selected for the heavy doping process IP2 is aluminum (Al), boron (B), gallium (Ga), or other suitable materials. In some embodiments, the first heavily doped area 132C in the first semiconductor part 132 and the second heavily doped area 134A in the second semiconductor part 134 include N-type silicon semiconductor, and the dopant selected for the heavy doping process IP2 is antimony (Sb), arsenic (As), phosphorus (P), or other suitable materials. In some embodiments, the first heavily doped area 132C in the first semiconductor part 132 and the second heavily doped area 134A in the second semiconductor part 134 may be referred to as P+ areas or N+ areas. The first doped area 132A and the first heavily doped areas 132C in the first semiconductor part 132, the second heavily doped areas 134A in the second semiconductor part 134, and the first doped area 132A in the capacitor area CR include the same dopant.

In some embodiments, the doping concentration of the first heavily doped areas 132C is greater than or substantially equal to the doping concentration of the first doped area 132A.

In some embodiments, since a portion of the first heavily doped areas 132C is also doped by the ion implantation process IP1, the portion of the first heavily doped areas 132C is doped by the ion implantation process IP1 (refer to FIG. 3E) in addition to the heavy doping process IP2, while another portion of the first heavily doped areas 132C is doped by the heavy doping process IP2 alone. In some embodiments, the doping concentration of the first heavily doped area 132C adjacent to the first doped area 132A is greater than or equal to the doping concentration of the first heavily doped area 132C adjacent to the first undoped area 132B.

Referring to FIG. 3K, an etch-back process is performed on the second gate part 164 and the first gate part 154 of the first active device area TR, the fourth gate part 166 and the third gate part 156 of the second active device area DG, and the electrode 168 of the capacitor area CR, to reduce the widths of the second gate part 164 and the first gate part 154 of the first active device area TR and expose a portion of the first doped area 132A and a portion of the first undoped area 132B located in the first active device area TR, reduce the widths of the fourth gate part 166 and the third gate part 156 of the second active device area DG and expose a portion of the second undoped area 134B located in the second active device area DG, and reduce the width of the electrode 168 of the capacitor area CR.

In some embodiments, the widths and thicknesses of the third sub-photoresist part PR2A, the fourth sub-photoresist part PR2B, the sixth photoresist part PR2C, and the seventh photoresist part PR2D of the second photoresist pattern PR2 are also reduced in the etch-back process.

Referring to FIG. 3L, using the second gate part 164 located in the first active device area TR and the fourth gate part 166 located in the second active device area DG as a light doping mask, a light doping process IP3 is performed on the semiconductor layer 130 outside the light doping mask to form a first lightly doped area 132D in a portion of the first undoped area 132B of the first active device area TR, and form two second lightly doped areas 134C in portions of the second undoped area 134B of the second active device area DG, and the second lightly doped areas 134C are separated from each other.

In some embodiments, the light doping process IP3 is performed after the third sub-photoresist part PR2A, the fourth sub-photoresist part PR2B, the sixth photoresist part PR2C, and the seventh photoresist part PR2D of the second photoresist pattern PR2 are removed, but the disclosure is not limited thereto.

In some embodiments, the first lightly doped area 132D of the first semiconductor part 132 and the second lightly doped area 134C in the second semiconductor part 134 include P-type silicon semiconductor, and the dopant selected for the light doping process IP3 is aluminum (Al), boron (B), gallium (Ga), or other suitable materials. In some embodiments, the first lightly doped area 132D of the first semiconductor part 132 and the second lightly doped area 134C in the second semiconductor part 134 include N-type silicon semiconductor, and the dopant selected for the light doping process IP3 is antimony (Sb), arsenic (As), phosphorus (P), or other suitable materials. In some embodiments, the first lightly doped area 132D of the first semiconductor part 132 and the second lightly doped areas 134C in the second semiconductor part 134 may be referred to as P-areas or N-areas. The first doped area 132A, the first heavily doped areas 132C, and the first lightly doped area 132D of the first semiconductor part 132, the second heavily doped areas 134A and the second lightly doped areas 134C in the second semiconductor part 134, and the first doped area 132A in the capacitor area CR include the same dopant.

In some embodiments, the doping concentration of the first doped area 132A is greater than the doping concentration of the first lightly doped area 132D. In some embodiments, the doping concentration of the first heavily doped area 132C is greater than or substantially equal to the doping concentration of the first doped area 132A.

Referring to FIG. 3M, the second photoresist pattern PR2 is removed, including the third sub-photoresist part PR2A located in the first active device area TR, the sixth photoresist part PR2C located in the second active device area DG, the seventh photoresist part PR2D located in the capacitor area CR, and the fourth sub-photoresist part PR2B located in the calibration mark area MR. In some embodiments, the second photoresist pattern PR2 is removed by an ashing process, a stripping process, or other suitable processes.

In this embodiment, the channel length and the variation in channel length of the protrusion gate channel bridge thin film transistor (PGCB TFT) in the first active device area TR are important parameters for evaluating the performance of this transistor. The smaller the variation in the channel length, the more stable the quality of the transistor.

In this embodiment, in the processes of FIG. 3H to FIG. 3M described above, the variation in the channel length depends on two variables. One is the length variation in the first undoped area 132B. The other is the alignment variation when performing alignment on the second conductive layer 160.

In this embodiment, the maximum shift of the length of the first undoped area 132B is 0.3 micrometers. The maximum shift when performing alignment on the second conductive layer 160 is related to the alignment of the second photoresist pattern PR2. In this embodiment, the position of the second photoresist pattern PR2 may be calibrated according to the first alignment component 152, and the maximum shift of the second photoresist pattern PR2, i.e., the maximum shift between the geometric center of the fourth sub-photoresist part PR2B and the geometric center of the first alignment component 152, is 0.4 micrometers.

Thus, the channel length variation of the protrusion gate channel bridge thin film transistor in the first active device area TR is the square of the maximum shift of the first undoped area 132B plus the square of the maximum shift when performing alignment on the second conductive layer 160, i.e., 0.3²+0.4²=0.25. Thus, the maximum shift of the channel length of the protrusion gate channel bridge thin film transistor in the first active device area TR is the square root of the variation, i.e., 0.5 micrometers.

Since only one alignment calibration during exposure is required in the process, i.e., calibrating the relative position of the second photoresist pattern PR2 with respect to the first alignment component 152, the problem of misalignment caused by the accumulation of process variations in the lithography process can be effectively reduced. Thus, the relative positions among the first gate part 154, the second gate part 164, and the first undoped area 132B are only affected by the process variation when forming the second photoresist pattern PR2, and are not affected by the process variation when forming the first photoresist pattern PR1.

Referring to FIG. 3N, an interlayer dielectric layer 170 is formed on the second gate part 164 and the first gate part 154 of the first active device area TR, the fourth gate part 166 and the third gate part 156 of the second active device area DG, the electrode 168 of the capacitor area CR, and the second alignment component 162 and the first alignment component 152 of at least one calibration mark area MR. In this embodiment, the interlayer dielectric layer 170 also covers the insulating layer 140. In some embodiments, the interlayer dielectric layer 170 may be configured not to cover the second alignment component 162 and the first alignment component 152 of the calibration mark area MR.

In some embodiments, the interlayer dielectric layer 170 has a single-layer or multi-layer structure, and its material includes silicon oxide, silicon nitride, silicon oxynitride, organic insulating material, other suitable materials, or combinations thereof. In some embodiments, multiple layers in the multi-layer structure of the interlayer dielectric layer 170 may have the same material or different materials. In some embodiments, the method of forming the interlayer dielectric layer 170 includes physical vapor deposition, chemical vapor deposition, atomic layer deposition, coating, or other suitable processes.

Referring to FIG. 3O, a first source 182, a first drain 184, a second source 186, and a second drain 188 are formed on the insulating layer 140 and the interlayer dielectric layer 170 to be electrically connected to the first heavily doped areas 132C of the first active device area TR and the second heavily doped areas 134A of the second active device area DG, respectively. Specifically, in some embodiments, multiple via holes are formed through the interlayer dielectric layer 170 and the insulating layer 140 by an etching process. These via holes expose the first heavily doped areas 132C of the first active device area TR and the second heavily doped areas 134A of the second active device area DG. These via holes respectively correspond to the positions of the first source 182, the first drain 184, the second source 186, and the second drain 188. In some embodiments, the first source 182, the first drain 184, the second source 186, and the second drain 188 have a single-layer or multi-layer structure, and their material includes metals such as chromium, gold, silver, copper, tin, lead, hafnium, tungsten, molybdenum, neodymium, titanium, tantalum, aluminum, zinc, nickel, etc., alloys thereof, metal oxides thereof, metal nitrides thereof, combinations thereof, or other conductive materials. In some embodiments, multiple layers in the multi-layer structure of the first source 182, the first drain 184, the second source 186, and the second drain 188 may have the same material or different materials. In some embodiments, the method of forming the first source 182, the first drain 184, the second source 186, and the second drain 188 includes sputtering, electroplating, electroless plating, physical vapor deposition, chemical vapor deposition, or other suitable processes.

A self-luminous component 190 is formed on, and electrically connected to, the first source 182 of the first active device area TR. In some embodiments, the self-luminous component 190 may also be located on the first drain 184, and the disclosure is not limited thereto. In some embodiments, the self-luminous component 190 may be an inorganic self-luminous component, an organic self-luminous component, or other suitable components. At least one control device electrically connected to the self-luminous component 190 may be referred to as a driving device, an emitting controller, or other devices.

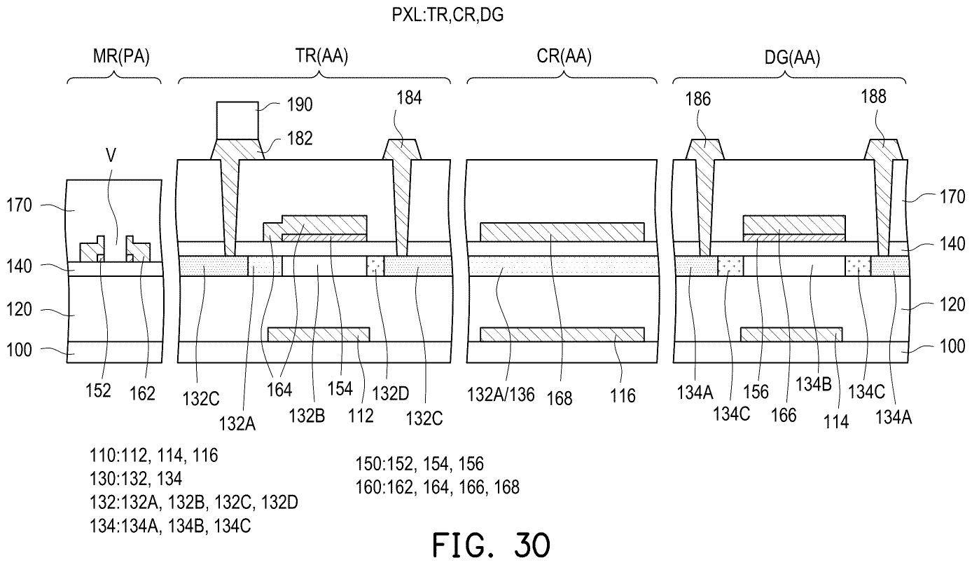

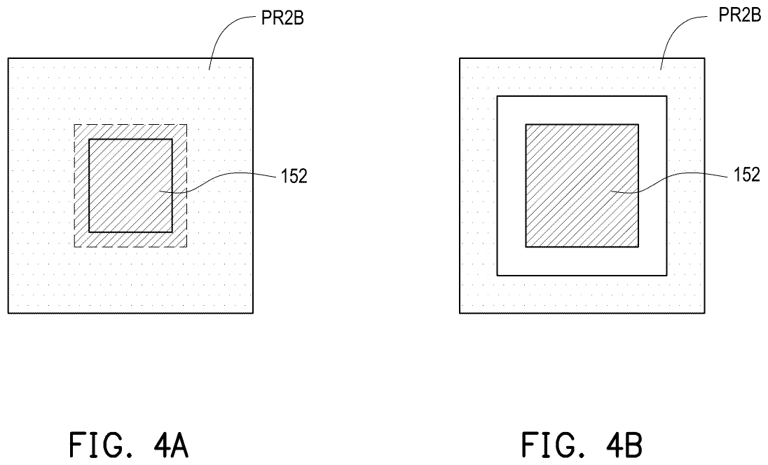

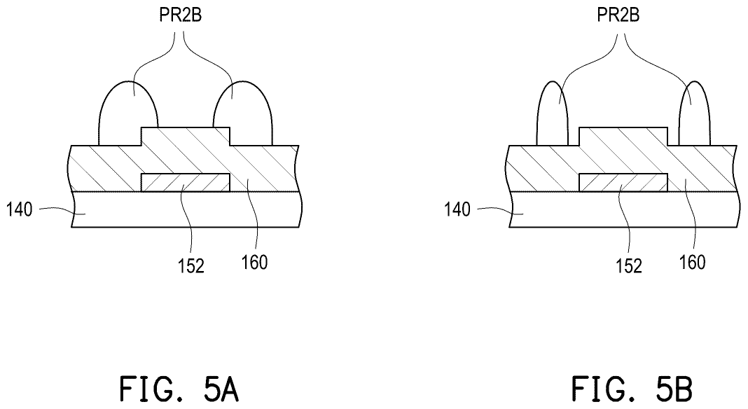

FIG. 4A is a top view of a calibration mark area according to an embodiment of the disclosure. FIG. 4B is a top view of a calibration mark area according to another embodiment of the disclosure. FIG. 5A is a cross-sectional view of the calibration mark area of FIG. 4A. FIG. 5B is a cross-sectional view of the calibration mark area of FIG. 4B.

Referring to both FIG. 4A and FIG. 5A, FIG. 4A and FIG. 5A are respectively a top view and a cross-sectional view of the fourth sub-photoresist part PR2B, the second conductive layer 160, and the first alignment component 152 of the calibration mark area MR in FIG. 3H. In this embodiment, the fourth sub-photoresist part PR2B partially covers the first alignment component 152 to thus position other portions of the second photoresist pattern PR2, including the third sub-photoresist part PR2A located in the first active device area TR, the sixth photoresist part PR2C located in the second active device area DG, and the seventh photoresist part PR2D located in the capacitor area CR.

In other embodiments, the fourth sub-photoresist part PR2B of the calibration mark area MR may have a different configuration relationship. Referring to both FIG. 4B and FIG. 5B, in this embodiment, the fourth sub-photoresist part PR2B surrounds, and does not cover, the first alignment component 152, to thus position other portions of the second photoresist pattern PR2, including the third sub-photoresist part PR2A located in the first active device area TR, the sixth photoresist part PR2C located in the second active device area DG, and the seventh photoresist part PR2D located in the capacitor area CR.

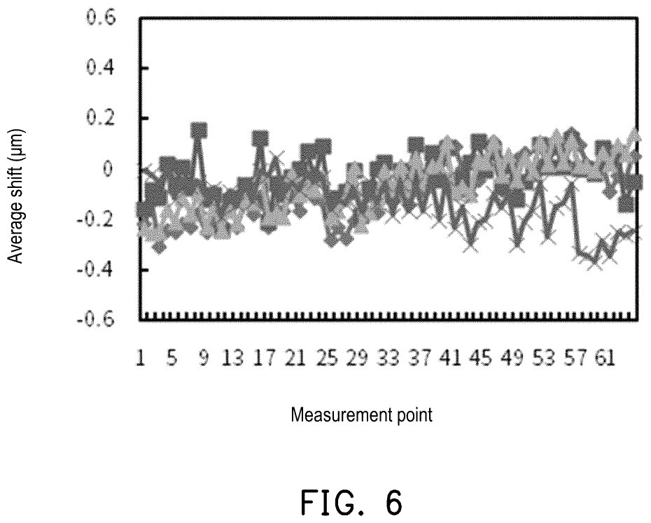

FIG. 6 shows an overlay distribution of the first gate part and the second gate part after disposing the first alignment component. As shown in FIG. 6, by disposing the first alignment component 152, the overlay shift of the first gate part 154 and the second gate part 164 is all less than +/−0.2 μm, indicating that the first alignment component 152 contributes to the determination of the position of the second gate part 164.

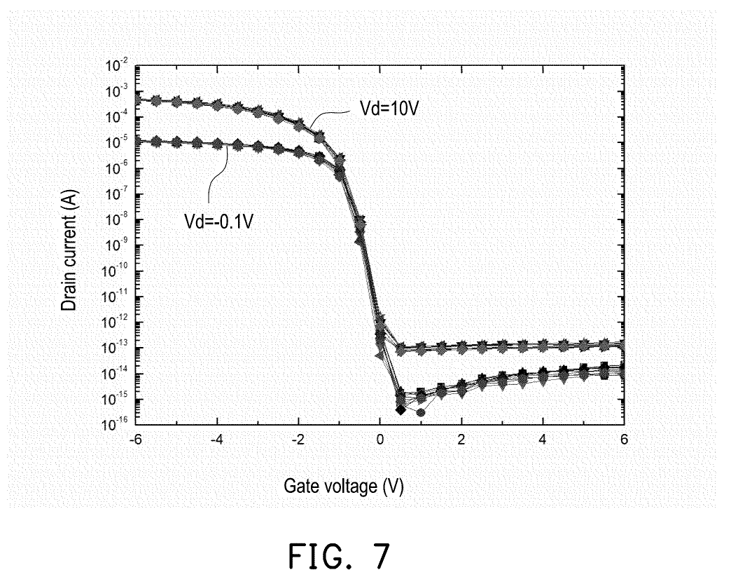

FIG. 7 shows an I-V curve at different voltages of a thin film transistor manufactured according to an embodiment of the disclosure. FIG. 7 shows the variation relationship between the gate voltage and the drain current upon applying different drain voltages (V_{d}) respectively to the thin film transistor (e.g., thin film transistor in the first active device area TR) obtained according to the manufacturing method provided by the embodiment of the disclosure. According to FIG. 7, the thin film transistor obtained according to the manufacturing method provided by the embodiment of the disclosure has good electrical properties.

In summary of the above, in the disclosure, the problem of shift of the first gate part 154, the second gate part 164, and the first undoped area 132B caused by excessive process variations can be avoided by disposing the first alignment component 152.

What is claimed is:

1. A manufacturing method of an active device substrate, comprising:
providing a substrate having a display area and a peripheral area located outside the display area, wherein the display area has at least one sub-pixel area, the sub-pixel area has a first active device area, and the peripheral area has at least one calibration mark area;
forming a light shielding layer on the substrate, wherein the light shielding layer has a first light shielding part located in the first active device area;
forming a buffer layer on the substrate, the buffer layer covering the first light shielding part;
forming a semiconductor layer on the buffer layer of the substrate, wherein the semiconductor layer has a first semiconductor part located in the first active device area;
forming an insulating layer on the buffer layer and the semiconductor layer, the insulating layer covering the first active device area and the at least one calibration mark area;
forming a first conductive layer on the insulating layer, the first conductive layer covering the first active device area and the at least one calibration mark area;
forming a first photoresist pattern on the first conductive layer, wherein the first photoresist pattern has a first sub-photoresist part and a second sub-photoresist part respectively located on the first active device area and the at least one calibration mark area;
etching the first conductive layer using the first photoresist pattern as an etching mask to respectively form a first alignment component on the at least one calibration mark area and a first gate part on the first active device area;
using the first gate part and the first sub-photoresist part located in the first active device area as a doping mask, performing an ion implantation process on the semiconductor layer outside the doping mask to form a first doped area and a first undoped area in the first semiconductor part of the first active device area, and removing the first photoresist pattern;
forming a second conductive layer on the insulating layer and on the first alignment component and the first gate part, the second conductive layer covering the first active device area and the at least one calibration mark area;
forming a second photoresist pattern on the second conductive layer, wherein the second photoresist pattern has a third sub-photoresist part and a fourth sub-photoresist part respectively located on the first active device area and the at least one calibration mark area, the third sub-photoresist part covers a portion of the second conductive layer on the first active device area and an overlapping portion of the second conductive layer overlapped with a portion of the first gate part, and the fourth sub-photoresist part has an opening to expose a portion of the second conductive layer in the at least one calibration mark area;
etching the second conductive layer using the second photoresist pattern as an etching mask to respectively form a second alignment component on the at least one calibration mark area and a second gate part on the first active device area and expose a portion of the first undoped area and a portion of the first doped area, wherein the second alignment component is located around the first alignment component, and portions of the second gate part overlap with the first gate part and the first doped area;
using the second gate part and the third sub-photoresist part located in the first active device area as a heavy doping mask, performing a heavy doping process on the semiconductor layer outside the heavy doping mask to respectively form two first heavily doped areas in a portion of the first doped area and a portion of the first undoped area of the first active device area, wherein the first heavily doped areas are separated from each other;
performing an etch-back process on the second gate part and the first gate part to reduce widths of the second gate part and the first gate part and expose a portion of the first doped area and a portion of the first undoped area located in the first active device area, and removing the second photoresist pattern;
using the second gate part located in the first active device area as a light doping mask, performing a light doping process on the semiconductor layer outside the light doping mask to form a first lightly doped area in a portion of the first undoped area of the first active device area; and
forming a first source and a first drain on the insulating layer to be respectively electrically connected to the first heavily doped areas of the first active device area.

2. The manufacturing method of an active device substrate according to claim 1, wherein the sub-pixel area further has a second active device area, the light shielding layer further has a second light shielding part located in the second active device area and the buffer layer further covers the second light shielding part, and the semiconductor layer further has a second semiconductor part located in the second active device area and the insulating layer further covers the second active device area, the manufacturing method further comprising:
forming the first conductive layer on the insulating layer, the first conductive layer covering the second active device area;
forming a fifth photoresist part of the first photoresist pattern on the first conductive layer on the second active device area;
etching the first conductive layer using the fifth photoresist part as an etching mask to form a third gate part on the second active device area;
forming the second conductive layer on the insulating layer and the third gate part, the second conductive layer covering the second active device area;
forming a sixth photoresist part of the second photoresist pattern on the second conductive layer on the second active device area;
etching the second conductive layer using the sixth photoresist part as an etching mask to form a fourth gate part on the second active device area and expose portions of the second semiconductor part, wherein the fourth gate part and the third gate part overlap with each other;
using the fourth gate part and the sixth photoresist part located in the second active device area as the heavy doping mask, performing the heavy doping process on the second semiconductor part outside the heavy doping mask to form two second heavily doped areas and a second undoped area in portions of the second semiconductor part of the second active device area, wherein the second heavily doped areas are separated from each other;
performing the etch-back process on the fourth gate part and the third gate part to reduce widths of the fourth gate part and the third gate part and expose portions of the second undoped area located in the second active device area;
using the fourth gate part located in the second active device area as the light doping mask, performing the light doping process on the semiconductor layer outside the light doping mask to form two second lightly doped areas in portions of the second undoped area of the second active device area, and removing the second photoresist pattern, wherein the second lightly doped areas are separated from each other; and
forming a second source and a second drain on the insulating layer to be respectively electrically connected to the second heavily doped areas of the second active device area.

3. The manufacturing method of an active device substrate according to claim 2, wherein the sub-pixel area further has a capacitor area, the light shielding layer further has a third light shielding part located in the capacitor area and the buffer layer further covers the third light shielding part, and the semiconductor layer further has a third semiconductor part located in the capacitor area and the insulating layer further covers the capacitor area, the manufacturing method further comprising:
forming the first conductive layer on the insulating layer, the first conductive layer covering the capacitor area;
etching the first conductive layer to expose the insulating layer on the capacitor area, and performing the ion implantation process on the third semiconductor part to form the first doped area in the third semiconductor part of the capacitor area;
forming the second conductive layer on the insulating layer, the second conductive layer covering the capacitor area;
forming a seventh photoresist part of the second photoresist pattern on the second conductive layer on the capacitor area; and
etching the second conductive layer using the seventh photoresist part as an etching mask to form an electrode on the capacitor area, wherein the electrode overlaps with a portion of the first doped area.

4. The manufacturing method of an active device substrate according to claim 3, further comprising:
performing the etch-back process on the electrode to reduce a width of the electrode.

5. The manufacturing method of an active device substrate according to claim 2, wherein the first heavily doped areas and the second heavily doped areas comprise a same dopant.

6. The manufacturing method of an active device substrate according to claim 1, wherein the second alignment component partially overlaps with the first alignment component, and there is a via at an overlapping portion of the second alignment component and the first alignment component.

7. The manufacturing method of an active device substrate according to claim 1, wherein a doping concentration of the first heavily doped areas is greater than or equal to a doping concentration of the first doped area.

8. The manufacturing method of an active device substrate according to claim 1, wherein the first heavily doped areas comprise a first first heavily doped area adjacent to the first doped area, and a second first heavily doped area adjacent to the first undoped area, and a doping concentration of the first first heavily doped area is greater than or equal to a doping concentration of the second first heavily doped area.

9. A display device comprising:
a substrate having a display area and a peripheral area located outside the display area, wherein the display area has at least one sub-pixel area, the sub-pixel area has a first active device area, and the peripheral area has at least one calibration mark area;
a light shielding layer disposed on the substrate and having a first light shielding part located in the first active device area;
a buffer layer disposed on the substrate and covering the first light shielding part;
a semiconductor layer disposed on the buffer layer of the substrate and having a first semiconductor part located in the first active device area, wherein the first semiconductor part has a first doped area, a first undoped area, a first lightly doped area, and two first heavily doped areas, the first doped area, the first undoped area, and the first lightly doped area are located between the first heavily doped areas, the first doped area is located between the first undoped area and one of the first heavily doped areas, and the first lightly doped area is located between the first undoped area and the other of the first heavily doped areas;
an insulating layer disposed on the buffer layer and the semiconductor layer and covering the first active device area and the at least one calibration mark area;
a first conductive layer disposed on the insulating layer and having a first alignment component located on the at least one calibration mark area and a first gate part located on the first active device area, wherein the first gate part overlaps with the first undoped area;
a second conductive layer disposed on the insulating layer and having a second alignment component located on the at least one calibration mark area and a second gate part located on the first active device area, wherein the second alignment component is located around the first alignment component, portions of the second gate part overlap with the first gate part and the first doped area, and the first gate part and the second gate part constitute a first gate; and
a first source and a first drain disposed on the insulating layer and respectively electrically connected to the first heavily doped areas of the first active device area.

10. The display device according to claim 9, wherein
the sub-pixel area further has a second active device area,
the light shielding layer further has a second light shielding part located in the second active device area and the buffer layer further covers the second light shielding part,
the semiconductor layer further has a second semiconductor part located on the second active device area and the insulating layer further covers the second active device area, wherein the second semiconductor part has a second undoped area, two second lightly doped areas, and two second heavily doped areas, the second undoped area and the second lightly doped areas are located between the second heavily doped areas, one of the second lightly doped areas is located between the second undoped area and one of the second heavily doped areas, the other of the second lightly doped areas is located between the second undoped area and the other of the second heavily doped areas,
the first conductive layer further has a third gate part located on the second active device area,
the second conductive layer further has a fourth gate part located on the second active device area, and the fourth gate part and the third gate part overlap with the second undoped area, and
the second active device area further comprises a second source and a second drain on the insulating layer to be respectively electrically connected to the second heavily doped areas of the second active device area.

11. The display device according to claim 10, wherein
the sub-pixel area further has a capacitor area, the light shielding layer further has a third light shielding part located in the capacitor area, and the buffer layer further covers the third light shielding part,
the semiconductor layer further has a third semiconductor part located in the capacitor area and the insulating layer further covers the capacitor area, wherein the third semiconductor part has the first doped area, and
the second conductive layer further has an electrode located on the capacitor area and overlapping with a portion of the first doped area.

12. The display device according to claim 10, wherein the first heavily doped areas and the second heavily doped areas comprise a same dopant.

13. The display device according to claim 9, wherein the second alignment component partially overlaps with the first alignment component, and there is a via at an overlapping portion of the second alignment component and the first alignment component.

14. The display device according to claim 9, further comprising at least one self-luminous component disposed on the substrate and electrically connected to the first drain or the first source on the first active device area.

15. The display device according to claim 9, wherein a doping concentration of the first heavily doped areas is greater than or equal to a doping concentration of the first doped area.

16. The display device according to claim 9, wherein the first heavily doped areas comprise a first first heavily doped area adjacent to the first doped area, and a second first heavily doped area adjacent to the first undoped area, and a doping concentration of the first first heavily doped area is greater than or equal to a doping concentration of the second first heavily doped area.
